(19) United States
(12) Patent Application Publication
(10) Pub. No.: US 2025/0063743 A1
(43) Pub. Date: Feb. 20, 2025

(54) IN-TRENCH CAPACITOR MERGED STRUCTURE

(71) Applicant: Taiwan Semiconductor Manufacturing Company, Ltd., Hsinchu (TW)

(72) Inventors: Shu-Hui SU, Tucheng City (TW); Hsin-Li CHENG, Hsinchu (TW); YingKit Felix TSUI, Cupertino, CA (US); Tuo-Hsin CHIEN, Zhubei City (TW); Jyun-Ying LIN, Wujie Township (TW); Shi-Min WU, Changhua County (TW); Yu-Chi CHANG, Kaohsiung City (TW); Ting-Chen HSU, Taichung City (TW)

(21) Appl. No.: 18/450,140

(22) Filed: Aug. 15, 2023

(51) Int. Cl. H10K 10/40

(52) U.S. Cl. CPC H01L 28/91

(57) ABSTRACT

Some implementations described herein provide techniques and apparatuses for an integrated circuit device including a trench capacitor structure that has a merged region. A material filling the merged region is different than a material that is included in electrode layers of the trench capacitor structure. Furthermore, the material filling the merged region includes a coefficient of thermal expansion and a modulus of elasticity that, in combination with the architecture of the trench capacitor structure, reduce thermally induced stresses and/or strains within the integrated circuit device relative to another integrated circuit device having a trench capacitor structure including a merged region and electrode layers of a same material.

### BACKGROUND

An integrated circuit (IC) device may include a trench capacitor region, where a multi-layer structure including layers of a conductive material interspersed with layers of a dielectric material conforms to sidewalls of a trench that penetrates vertically into a semiconductor substrate. The trench capacitor region may increase a capacitance of the IC device while preserving area of the IC device for other IC device structures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an example semiconductor die package including an in-trench capacitor merged structure described herein.

FIGS. 3A and 3B are diagrams of example implementation of an in-trench capacitor merged structure described herein.

FIGS. 4A-4G are diagrams of an example implementation of forming an in-trench capacitor merged structure described herein.

FIGS. 5A-5D are diagrams of an example implementation of forming a semiconductor die described herein.

FIGS. 6A-6E are diagrams of an example implementation of forming a semiconductor die described herein.

FIGS. 7A-7G are diagrams of an example implementation of forming a portion of a semiconductor die package described herein.

FIG. 8 is a diagram of example components of a device described herein.

FIG. 9 is a flowchart of an example process associated with forming an in-trench capacitor merged structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, an IC device includes a trench capacitor structure having a merged region. Furthermore, a material filling the merged region may be a same material that is included in electrode layers of the trench capacitor structure. During a deposition operation at an elevated temperature, the coefficient of thermal expansion and the modulus of elasticity of the material filling the merged region, in combination with an architecture of the trench capacitor structure, may induce failures to the IC device during manufacturing. For example, a titanium nitride material (TiN) of the electrode layers and filling the merged region may include a coefficient of thermal expansion (CTE) and a modulus of elasticity that, in combination with the architecture of the trench capacitor structure, induce thermal stresses and/or strains within the IC device during a deposition operation at an elevated temperature. Such thermal stresses and/or strains may cause cracking defects within the IC device during the deposition operation.

Some implementations described herein provide techniques and apparatuses for an IC device including a trench capacitor structure that has a merged region. A material filling the merged region is different than a material that is included in electrode layers of the trench capacitor structure. Furthermore, the material filling the merged region includes a coefficient of thermal expansion and a modulus of elasticity that are lesser relative to a coefficient of thermal expansion and a modulus of elasticity of the material that is included in the electrode layers. During a deposition operation at an elevated temperature, the coefficient of thermal expansion and the modulus of elasticity of the material filling the merged region, in combination with the architecture of the trench capacitor structure, reduce thermally induced stresses and/or strains within the IC device relative to another IC device having another trench capacitor structure including a merged region and electrode layers of a same material. By reducing the thermal stresses and/or strains within the IC device, a likelihood of cracking defects is reduced.

In this way, a quality and/or a reliability of the IC device may be improved to increase a manufacturing yield and reduce an amount of latent field failures during use of the IC device. By improving the manufacturing yield and reducing the amount of latent field failures, an amount of resources to manufacture and support a volume of the IC device (e.g., power, labor, semiconductor manufacturing tools, raw materials, and/or computing resources to manufacture the IC device and/or manage returns of the IC device) may be reduced.

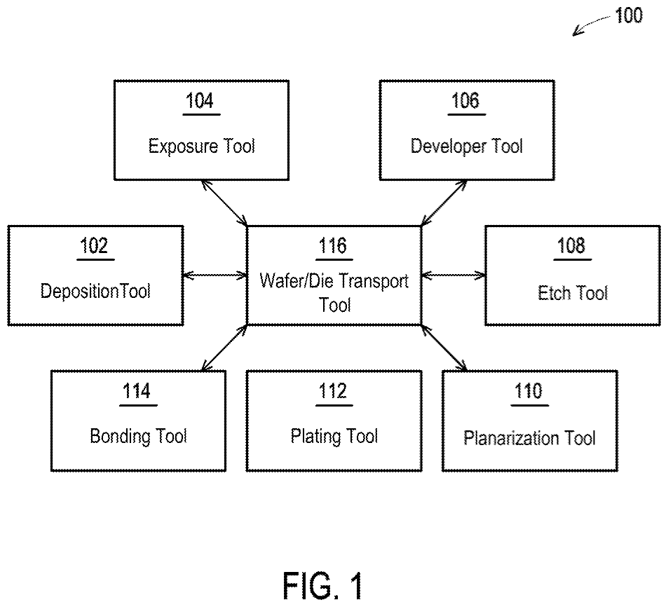

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-112 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The bonding tool 114 is a semiconductor processing tool that is capable of bonding two or more work pieces (e.g., two or more semiconductor substrates, two or more semiconductor devices, two or more semiconductor dies) together. For example, the bonding tool 114 may be a direct bonding tool that is a type of bonding tool that is configured to bond semiconductor dies together directly through copper-to-copper (or other direct metal) connections. As another example, the bonding tool 114 may include a eutectic bonding tool that is capable of forming a eutectic bond between two or more wafers together. In these examples, the bonding tool 114 may heat the two or more wafers to form a eutectic system between the materials of the two or more wafers.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-114, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102.

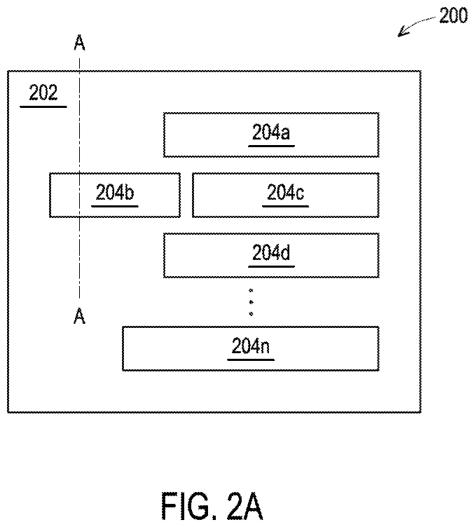

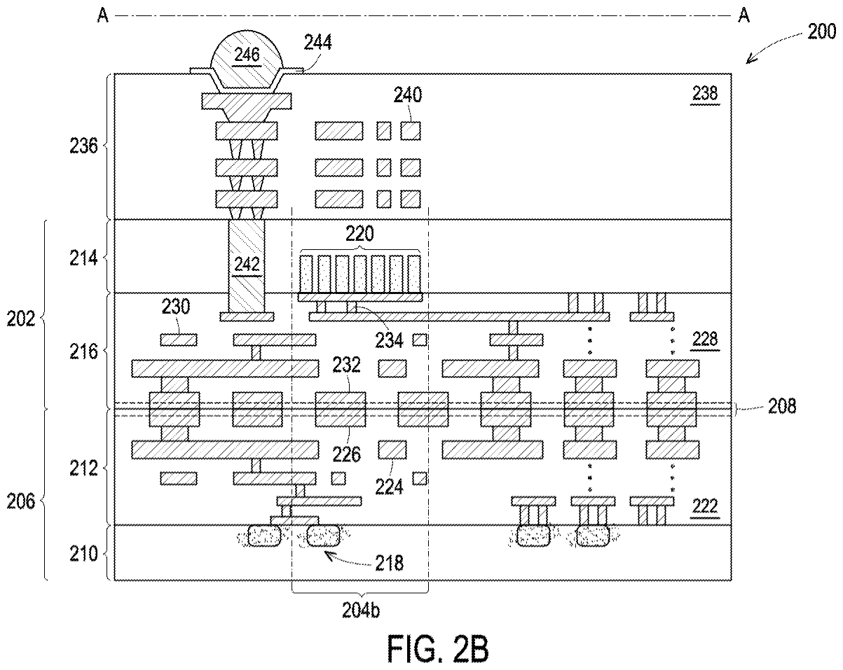

In some implementations, and as described in greater detail in connection with FIGS. 2A-9, one or more of the semiconductor processing tools 102-114 and/or the wafer/die transport tool 116 may be used to perform a series of semiconductor processing operations. The series of semiconductor processing operations includes forming an insulator layer of a trench capacitor structure on a substrate including a first material having a first coefficient of thermal expansion. The series of semiconductor processing operations includes forming an electrode layer of the trench capacitor structure on the insulator layer from a second material having a second coefficient of thermal expansion that is greater relative to the first coefficient of thermal expansion. The series of semiconductor processing operations includes forming a merged dielectric layer in a gap between co-facing surfaces of the electrode layer from a third material having a third coefficient of thermal expansion that is lesser relative to the first coefficient of thermal expansion.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may be used to perform one or more functions described as being performed by another set of devices of the example environment 100.

FIGS. 2A and 2B are diagrams of an example semiconductor die package 200 including an in-trench capacitor merged structure described herein. The semiconductor die package 200 includes an example of a wafer on wafer (WoW) semiconductor die package, a die on wafer semiconductor die package, a die-on-die semiconductor die package, or another type of semiconductor die package in which semiconductor dies are directly bonded and vertically arranged or stacked. FIG. 2A illustrates a top-down view of a portion of the semiconductor die package 200, including a reference section line A-A used in connection with FIG. 2B.

As shown in FIG. 2A, the semiconductor die package 200 may include a first semiconductor die 202 and a plurality of trench capacitor regions 204a-204n in the first semiconductor die 202. The trench capacitor regions 204a-204n may be horizontally arranged in the first semiconductor die 202. The trench capacitor regions 204a-204n may include various sizes and/or shapes to provide a sufficient amount of decoupling capacitance across the semiconductor die package 200 for the circuits and semiconductor devices of the semiconductor die package 200.

As shown in FIG. 2B (e.g., a section view along A-A of FIG. 2A), the semiconductor die package 200 includes the first semiconductor die 202 and a second semiconductor die 206. In some implementations, the semiconductor die package 200 includes additional semiconductor dies. The first semiconductor die 202 may include an SoC die, such as a logic die, a central processing unit (CPU) die, a graphics processing unit (GPU) die, a digital signal processing (DSP) die, an application specific integrated circuit (ASIC) die, and/or another type of SoC die. Additionally, and/or alternatively, the first semiconductor die 202 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The second semiconductor die 206 may include the same type of semiconductor die as the first semiconductor die 202, or may include a different type of semiconductor die.

The first semiconductor die 202 and the second semiconductor die 206 may be bonded together (e.g., directly bonded) at a bonding interface 208. In some implementations, one or more layers may be included between the first semiconductor die 202 and the second semiconductor die 206 at the bonding interface 208, such as one or more passivation layers, one or more bonding films, and/or one or more layers of another type.

The second semiconductor die 206 may include a device region 210 and an interconnect region 212 adjacent to and/or above the device region 210. In some implementations, the second semiconductor die 206 may include additional regions. Similarly, the first semiconductor die 202 may include a device region 214 and an interconnect region 216 adjacent to and/or below the device region 214. In some implementations, the first semiconductor die 202 may include additional regions. The first semiconductor die 202 and the second semiconductor die 206 may be bonded at the interconnect region 212 and the interconnect region 216. The bonding interface 208 may be located at a first side of the interconnect region 216 facing the interconnect region 212 and corresponding to a first side of the second semiconductor die 202.

The device regions 210 and 214 may each include a semiconductor substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate. The device region 210 of the second semiconductor die 206 may include one or more semiconductor devices 218 included in the semiconductor substrate of the device region 210. The semiconductor devices 218 may include one or more transistors (e.g., planar transistors, fin field effect transistors (FinFETs), nanosheet transistors (e.g., gate all around (GAA) transistors), memory cells, capacitors, inductors, resistors, pixel sensors, circuits (e.g., integrated circuits (ICs)), and/or another type of semiconductor devices. In some implementations, the device region 210 includes logic circuitry.

As further shown in FIG. 2B, the device region 214 of the first semiconductor die 202 (e.g., an IC device) may include a trench capacitor structure 220 in the semiconductor substrate of the device region 214 (e.g., within the trench capacitor region 204b of FIG. 2A). A depth of the trench capacitor structure 220 may be selected to provide sufficient capacitance so as to satisfy circuit decoupling parameters for the semiconductor devices 218 included in circuits of the semiconductor die package 200, while reducing the likelihood of warping, breaking, and/or cracking of the semiconductor die package 200. Some of the circuits of the semiconductor die package 200 may have greater decoupling capacitance requirements than other circuits in order to properly operate at desired performance parameters. Accordingly, deeper trench capacitor structures may be formed for these circuits relative to the depth of trench capacitor structures that are formed for other circuits that have lesser decoupling capacitance requirements. This enables a balance between satisfying capacitance requirements in the semiconductor die package 200.

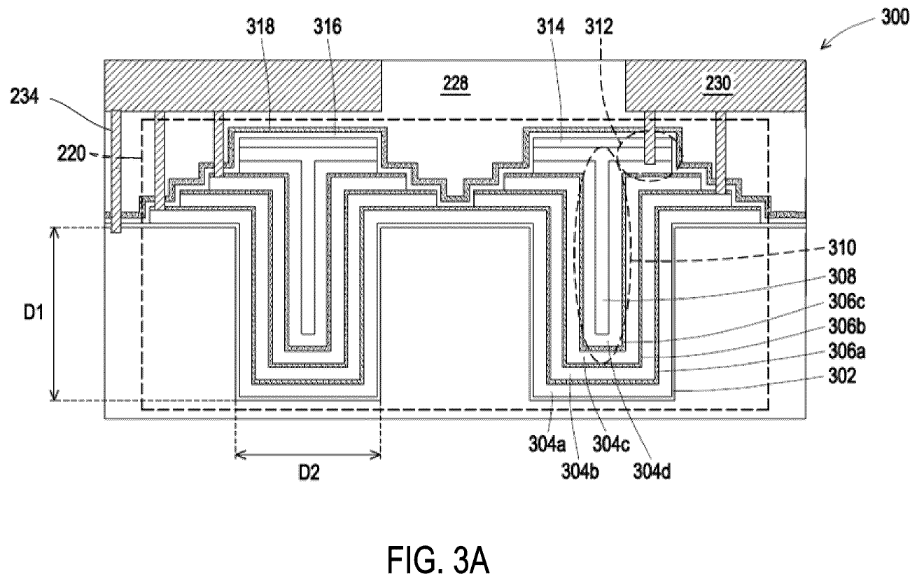

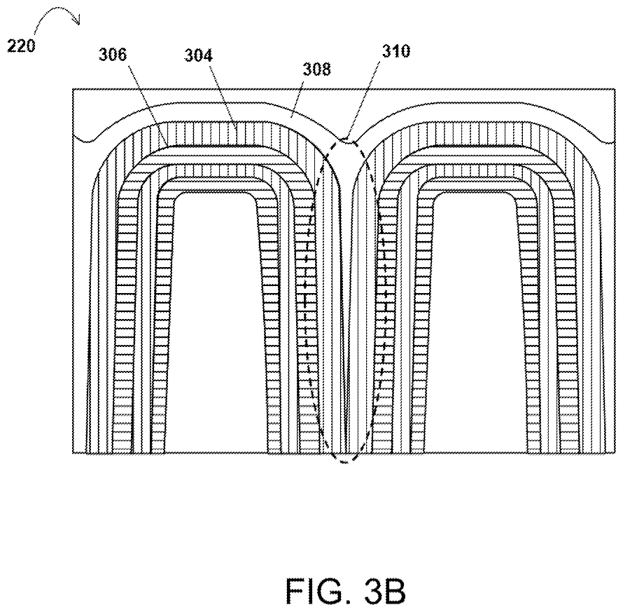

As described in greater detail in connection with FIGS. 3A-9, the trench capacitor structure 220 includes a plurality of electrode layers of a first material, where the first material has a first modulus of elasticity, and a plurality of insulator layers interspersed with the plurality of electrode layers. The trench capacitor structure includes a merged dielectric layer of a second material in a merge region between co-facing surfaces of a top-most insulator layer of the plurality of insulator layers, where the second material has a second modulus of elasticity that is lesser relative to the first modulus of elasticity.

Additionally, or alternatively, the trench capacitor structure 220 includes a plurality of electrode layers of a first material, where the first material has a first coefficient of thermal expansion, and a plurality of insulator layers interspersed with the plurality of electrode layers. The trench capacitor structure 220 includes a merged dielectric layer of a second material in a merge region between co-facing surfaces of a top-most layer of the plurality of electrode layers, where the second material has a second coefficient of thermal expansion that is lesser relative to the first coefficient of thermal expansion.

During a deposition operation that forms the trench capacitor structure 220, the coefficient of thermal expansion and the modulus of elasticity of the second material filling the merged region, in combination with the architecture of the trench capacitor structure 220, reduces thermally induced stresses and/or strains within the semiconductor die 202 (e.g., an IC device) relative to another trench capacitor structure including a merged dielectric layer and electrode layers of a same material. By reducing the thermal stresses and/or strains within the semiconductor die 202, a likelihood of cracking defects is reduced.

In this way, a quality and/or a reliability of the semiconductor die package 200 including the semiconductor dies 202 and 206 (e.g., IC devices) may be improved to increase a manufacturing yield and reduce an amount of latent field failures during use of the semiconductor die package 200. By improving the manufacturing yield and reducing the amount of latent field failures, an amount of resources to manufacture and support a volume of the semiconductor die package 200, (e.g., power, labor, semiconductor manufacturing tools, raw materials, and/or computing resources to manufacture the semiconductor dies 202 and 206 and/or manage returns of the semiconductor die package 200) may be reduced.

In some implementations, the interconnect regions 212 and 216 are referred to as back end of line (BEOL) regions. The interconnect region 212 may include one or more dielectric layers 222, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the dielectric layer(s) 222. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 212 may further include one or more metallization layer(s) 224 in the dielectric layer(s) 222. The semiconductor devices 218 in the device region 210 may be electrically connected and/or physically connected with one or more of the metallization layer(s) 224. The metallization layer(s) 224 may include conductive lines, trenches, vias, pillars, interconnects, and/or another type of metallization layers. Contacts 226 may be included in the dielectric layer(s) 222 of the interconnect region 212. The contact(s) 226 may be electrically connected and/or physically connected with one or more of the metallization layer(s) 224. The contact(s) 226 may include conductive terminals, conductive pads, conductive pillars, under bump metallization (UBM) structures, and/or another type of contacts. The metallization layer(s) 224 and the contact(s) 226 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The interconnect region 216 may include one or more dielectric layer(s) 228, which may include a silicon nitride (SiNₓ), an oxide (e.g., a silicon oxide (SiOₓ) and/or another oxide material), a low dielectric constant (low-k) dielectric material, and/or another type of dielectric material. In some implementations, one or more etch stop layers (ESLs) may be included in between layers of the dielectric layer(s) 228. The one or more ESLs may include aluminum oxide (Al₂O₃), aluminum nitride (AlN), silicon nitride (SiN), silicon oxynitride (SiOₓN_{y}), aluminum oxynitride (AlON), and/or a silicon oxide (SiOₓ), among other examples.

The interconnect region 216 may further include one or more metallization layers 230 in the dielectric layer(s) 228. The trench capacitor structure 220a-220c in the device region 214 may be electrically connected and/or physically connected with one or more of the metallization layer(s) 230. The metallization layer(s) 230 may include conductive lines, trenches, vias, pillars, interconnects, and/or another type of metallization layers. Contacts 232 may be included in the dielectric layer(s) 228 of the interconnect region 216. The contact(s) 232 may be electrically connected and/or physically connected with one or more of the metallization layer(s) 230. Moreover, the contact(s) 232 may be electrically and/or physically connected with the contact(s) 226 of the second semiconductor die 206. The contact(s) 232 may include conductive terminals, conductive pads, conductive pillars, UBM structures, and/or another type of contacts. The metallization layer(s) 230 and the contact(s) 232 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The interconnect region 216 may include one or more interconnect structures 234. The interconnect structure(s) 234 (e.g., vertical interconnect access structures, or vias) may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials. The interconnect structure(s) 234 may provide an electrical connection between one or more of the metallization layer(s) 230. Additionally, or alternatively, the interconnect structure(s) 234 may connect the trench capacitor structure 220 to a metallization layer of the one or more metallization layers.

As further shown in FIG. 2B, the semiconductor die package 200 may include a redistribution structure 236. The redistribution structure 236 may include a redistribution layer (RDL) structure, an interposer, a silicon-based interposer, a polymer-based interposer, and/or another type of redistribution structure. The redistribution structure 236 may be configured to fan out and/or route signals and I/O of the semiconductor dies 202 and 206.

The redistribution structure 236 may include one or more dielectric layers 238 and a plurality of metallization layers 240 disposed in the one or more dielectric layers 238. The dielectric layer(s) 238 may include polybenzoxazole (PBO), a polyimide, a low temperature polyimide (LTPI), an epoxy resin, an acrylic reason, a phenol resin, benzocyclobutene (BCB), one or more dielectric layers, and/or another suitable dielectric material.

The metallization layers 240 of the redistribution structure 236 may include one or more materials such as a gold (Au) material, a copper (Cu) material, a silver (Ag) material, a nickel (Ni) material, a tin (Sn) material, and/or a palladium (Pd) material, among other examples. The metallization layers 240 of the redistribution structure 236 may include metal lines, vias, interconnects, and/or another type of metallization layers.

As further shown in FIG. 2B, the semiconductor die package 200 may include one or more backside through silicon via (BTSV) structures 242 through the device region 214, and into a portion of the interconnect region 216 of the first semiconductor die 202. The BTSV structure(s) 242 may include vertically elongated conductive structures (e.g., conductive pillars, conductive vias) that electrically connect one or more of the metallization layer(s) 230 in the interconnect region 216 of the first semiconductor die 202 to one or more metallization layers 240 in the redistribution structure 236. The BTSV structures 242 may be referred to as through silicon via (TSV) structures in that the BTSV structures 242 extend fully through a semiconductor substrate (e.g., a silicon substrate) of the device region 214 as opposed to extending fully through a dielectric layer or an insulator layer. The BTSV structure(s) 242 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

UBM layers 244 may be included on a top surface of the one or more dielectric layers 238. The UBM layers 244 may be electrically connected and/or physically connected with one or more metallization layers 240 in the redistribution structure 236. The UBM layers 244 may be included in recesses in the top surface of the one or more dielectric layers 238. The UBM layers 244 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

As further shown in FIG. 2B, the semiconductor die package 200 may include conductive terminals 246. The conductive terminals 246 may be electrically connected and/or physically connected with the UBM layers 244. The UBM layers 244 may be included to facilitate adhesion to the one or more metallization layers 240 in the redistribution structure 236, and/or to provide increased structural rigidity for the conductive terminals 246 (e.g., by increasing the surface area to which the conductive terminals 246 are connected). The conductive terminals 246 may include ball grid array (BGA) balls, land grid array (LGA) pads, pin grid array (PGA) pins, and/or another type of conductive terminals. The conductive terminals 246 may enable the semiconductor die package 200 to be mounted to a circuit board, a socket (e.g., an LGA socket), an interposer or redistribution structure of a semiconductor device package (e.g., a chip on wafer on substrate CoWoS package, an integrated fanout (InFO) package), and/or another type of mounting structure.

As indicated above, FIGS. 2A and 2B are provided as an example. Other examples may differ from what is described with regard to FIGS. 2A and 2B.

FIGS. 3A and 3B are diagrams of an example implementation 300 of an in-trench capacitor merged structure described herein. The in-trench capacitor merged structure may correspond to the trench capacitor structure 220 of FIG. 2. In some implementations, and as shown in FIG. 3A, the trench capacitor structure 220 includes a high aspect ratio, where a depth D1 of one or more trenches of the trench capacitor structure 220 is greater that a width D2 of the one or more trenches.

As shown in FIG. 3A, the trench capacitor structure 220 may be formed in the device region 214 (e.g., the substrate of the device region 214). In some implementations, and as shown in FIG. 3A, the trench capacitor structure 220 includes a liner layer 302. The liner layer 302 may include a dielectric material, such a silicon oxide material (SiO₂) or a silicon nitride material (SiN), among other examples. The trench capacitor structure 220 may include a plurality of conductive layers 304 and a plurality of dielectric layers 306. The plurality of conductive layers 304 and the plurality of dielectric layers 306 may be interspersed with one another using alternating configuration in the trench capacitor structure 220. For example, a first conductive layer 304a may be included in the trench capacitor structure 220, a first dielectric layer 306a may be included over the first conductive layer 304a, a second conductive layer 304b may be included over the first dielectric layer 306a, and so on. A dielectric layer 306 between a pair of conductive layers 304 may correspond to a trench capacitor (e.g., a capacitor plate) of the trench capacitor structure 220, where the conductive layers 304 correspond to the electrode layers of the trench capacitor structure 220s and the dielectric layers 306 correspond to insulator layers of the trench capacitor structure 220. In this way, the trench capacitor structure 220 includes a plurality of layered trench capacitors that extend into the semiconductor substrate of the device region 214.

In general, a deeper trench capacitor structure 220 may provide a greater amount of decoupling capacitance relative to a shallower trench capacitor structure 220. Additionally, and/or alternatively, a wider trench capacitor structure 220 may include a greater quantity of conductive layers 304 and a greater quantity of dielectric layers 306 and, therefore, a greater quantity of trench capacitors relative to a narrower trench capacitor structure 220. This enables a wider trench capacitor structure 220 to also provide a greater amount of capacitance relative to a narrower trench capacitor structure 220.

The conductive layers 304 may include one or more conductive materials, such as a conductive metal (e.g., copper (Cu), tungsten (W), titanium (Ti), tantalum (Ta), ruthenium (Ru), cobalt (Co)), a conductive ceramic (e.g., tantalum nitride (TaN), titanium nitride (TiN)), and/or another type of conductive material. The dielectric layers 306 may include one or more dielectric materials such as an oxide (e.g., silicon oxide (SiOₓ)), a nitride (e.g., silicon nitride (SiₓN_{y}), and/or another suitable dielectric material.

As further shown in FIG. 3A, the conductive layers 304 and the dielectric layers 306 may partially extend out of the semiconductor substrate of the device region 214 and may extend along a portion of the surface of the semiconductor substrate of the device region 214. This enables the conductive layers 304 to be electrically connected with one or more metallization layers (e.g., the metallization layer(s) 230 of the semiconductor die 202) using one or more connection structures (e.g., the interconnect structure(s) 234).

As further shown in FIG. 3A, the trench capacitor structure 220 includes a merged dielectric layer 308, including a portion in a merge region 310 and a portion extending into a lateral region 312 (e.g., a portion above the conductive layer 304d). As shown in FIG. 3A, the portion extending into the lateral region 312 is outside the merge region 310. Further, and as shown in FIG. 3A, the interconnect structure 234 passes through the portion and to the conductive layer 304d (e.g., a top-most electrode layer).

The merged dielectric layer 308 may include an oxide material such as aluminum oxide material (Al₂O₃), a zirconium oxide material (ZrO₂), or a silicon dioxide material (SiO₂), among other examples. Alternatively, the merged dielectric layer 308 may include a polyimide material.

As shown in FIG. 3A, the merge region 310 is between co-facing surfaces of the conductive layer 304d (e.g., between co-facing surfaces of the top-most electrode layer). Additionally, or alternatively and as further shown in FIG. 3A, the merge region 310 is between co-facing surfaces of the dielectric layer 306c (e.g., between co-facing surfaces of a top-most insulator layer).

Combinations of materials within the trench capacitor structure 220 may be selected to reduce a shrinkage strain within the merge region 310 during a deposition operation (e.g., during a deposition operation having a thermal cycle that includes a cooling duration). For example, a material of the merged dielectric layer 308 may include a coefficient of thermal expansion (CTE) that is lesser relative to a CTE of a material of the conductive layers 304. For example, in a case where the conductive layers 304 include a TiN material having a CTE of approximately 9.35 parts per million per degree Celsius (ppm/° C.), the merged dielectric layer 308 may include an SiO₂ material having a CTE of approximately 0.35 ppm/° C. If the CTE of the material of the merged dielectric layer 308 is approximately equal to (or greater than) the CTE of the material of the conductive layers 304, a shrinkage strain and/or thermally induced stress within the merge region 310 may not be sufficiently reduced to reduce a likelihood of delamination and/or cracking defects within the trench capacitor structure 220 (e.g., during the thermal cycle of the deposition operation).

Additionally, or alternatively, a material of the merged dielectric layer 308 may include a CTE that is lesser relative to a CTE of a material of a substrate of the device region 214. For example, in a case where the substrate of the device region 214 includes an Si material having a CTE of approximately 2.6 ppm/° C., the merged dielectric layer 308 may include an SiO₂ material having a CTE of approximately 0.35 ppm/° C. Further, and in such a case, the substrate of the device region 214 may include a material having a CTE (e.g., the Si material having the CTE of approximately 0.35 ppm/° C.) that is lesser relative to that of the conductive layers 304 (e.g., the TiN material having the CTE of approximately 9.35 ppm/° C.).

Additionally, or alternatively, a ratio of a CTE of a material of a substrate of the device region 214 to a CTE of a material of the merged dielectric layer 308 may be greater than approximately 7:1. If the ratio of the CTE of a material of a substrate of the device region 214 to a CTE of a material of the merged dielectric layer 308 is lesser than approximately 7:1, a shrinkage strain and/or thermally induced stress within the merge region 310 may not be sufficiently reduced to reduce a likelihood of delamination and/or cracking defects within the trench capacitor structure 220 (e.g., during the thermal cycle of the deposition operation).

Additionally, or alternatively, a material of the merged dielectric layer 308 includes a modulus of elasticity (e.g., a Young's modulus) that is lesser relative to a modulus of elasticity of a material of the conductive layers 304. For example, in a case where the conductive layers 304 include a TiN material having a modulus of elasticity of approximately 251 gigapascal (GPa), the merged dielectric layer 308 may include an SiO₂ material having a modulus of elasticity of approximately 70 GPa. If the modulus of elasticity of the material of the merged dielectric layer 308 is approximately equal to (or greater than) the modulus of elasticity of the material of the conductive layers 304, a shrinkage strain and/or thermally induced stress within the merge region 310 may not be sufficiently reduced to reduce a likelihood of delamination and/or cracking defects within the trench capacitor structure 220 (e.g., during the thermal cycle of the deposition operation).

Additionally, or alternatively, a material of the merged dielectric layer 308 may include a modulus of elasticity that is lesser relative to a modulus of elasticity of a material of a substrate of the device region 214. For example, in a case where the substrate of the device region 214 includes an Si material having a modulus of elasticity of approximately 190 GPa, the merged dielectric layer 308 may include an SiO₂ material having a modulus of elasticity of approximately 70 GPa. If the modulus of elasticity of the material of the merged dielectric layer 308 is approximately equal to (or greater than) the modulus of elasticity of the material of the substrate of the device region 214, a shrinkage strain and/or thermally induced stress within the merge region 310 may not be sufficiently reduced to reduce a likelihood of delamination and/or cracking defects within the trench capacitor structure 220 (e.g., during the thermal cycle of the deposition operation).

Additionally, or alternatively, a material of the substrate of the device region 214 may include a material having a CTE (e.g., the Si material having modulus of elasticity of approximately 190 GPa) that is lesser relative to that of the conductive layers 304 (e.g., the TIN material having the modulus of elasticity that is approximately 251 GPa. If the modulus of elasticity of the material of the substrate of the device region 214 is approximately equal to (or greater than) the modulus of elasticity of the material the conductive layers 304, a shrinkage strain and/or thermally induced stress within the merge region 310 may not be sufficiently reduced to reduce a likelihood of delamination and/or cracking defects within the trench capacitor structure 220 (e.g., during the thermal cycle of the deposition operation).

Further, and in some implementations, a ratio of a modulus of elasticity of a material of a substrate of the device region 214 to a modulus of elasticity of a material of the merged dielectric layer 308 may be greater than approximately 5:2. If the ratio of modulus of elasticity of a material of a substrate of the device region 214 to a modulus of elasticity of material of the merged dielectric layer 308 is lesser than approximately 5:2, a shrinkage strain and/or a thermally induced stress within the merge region 310 may not be sufficiently decreased to reduce a likelihood of delamination and/or cracking defects within the trench capacitor structure 220 (e.g., during the thermal cycle of the deposition operation).

As shown in FIG. 3A, the trench capacitor structure 220 may include bottom anti-reflective coating (BARC) layer 314, an oxide layer 316, and/or a silicon nitride (SiN) layer 318. In some implementations, the oxide layer 316 combines with the SiN layer 318 to form an etch stop layer that may be used during formation of the trench capacitor structure 220.

The values, ratios, and combinations of the CTEs and the moduli of elasticity for the device region 214, the conductive layers 304, and the merged dielectric layer 308 are provided as one or more examples. However, other values, ratios, and combinations of the CTEs and the moduli of elasticity are within the scope of the present disclosure.

Furthermore, the trench capacitor structure 220 of FIG. 3A is provided as an example, and may include additional features not shown in FIG. 3A. For example, an additional insulator layer or liner layer may be included in the trench capacitor structure 220 between the merged dielectric layer 308 and a top-most electrode layer (e.g., the conductive layer 304d). In such a case, and in contrast to being on the top-most electrode layer, the merged dielectric layer 308 may be on a top-most insulator layer or a top-most liner layer.

FIG. 3B shows a side view of the trench capacitor structure 220, including the conductive layers 304, the dielectric layers 306, and the merged dielectric layer 308. As shown in FIG. 3B, the merged dielectric layer 308 excludes co-facing surfaces that are in contact with each other and that form an interface (e.g., an interface within the merge region 310). In addition to the effects of CTE and modulus of elasticity combinations on thermal strains and/or stresses as described in connection with FIG. 3A, the exclusion of the co-facing surfaces (e.g., the exclusion of the interface, which may include discontinuities) reduces a likelihood of delamination, cracking, and/or other defects within the trench capacitor structure 220.

As indicated above, FIGS. 3A and 3B are provided as an example. Other examples may differ from what is described with regard to FIGS. 3A and 3B.

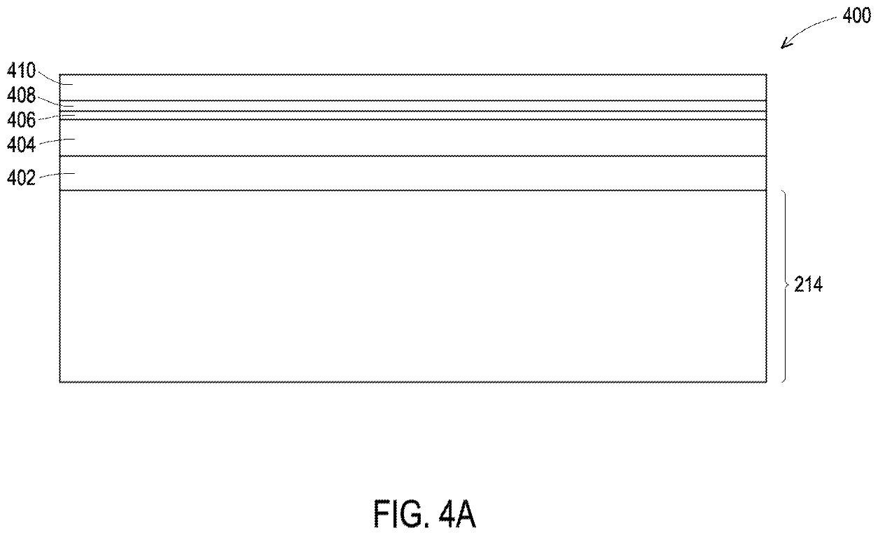

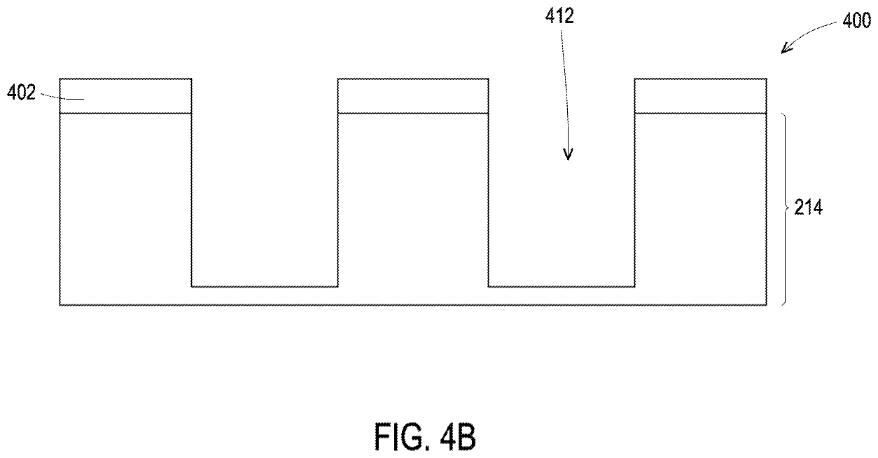

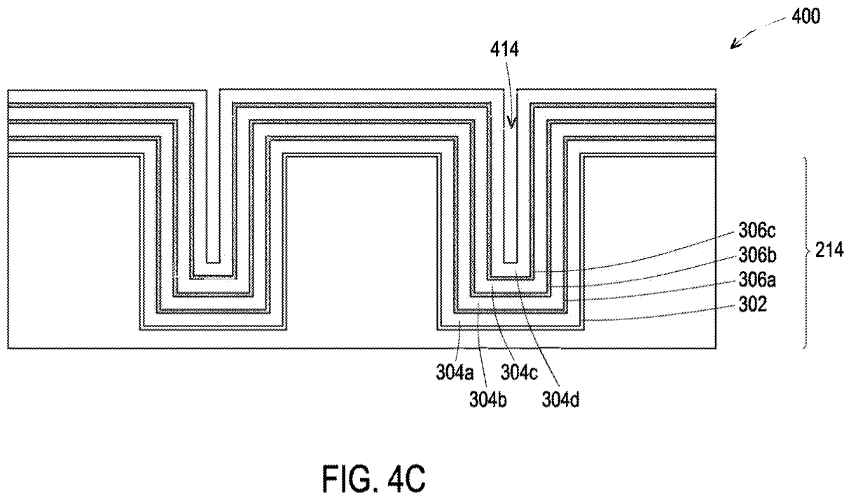

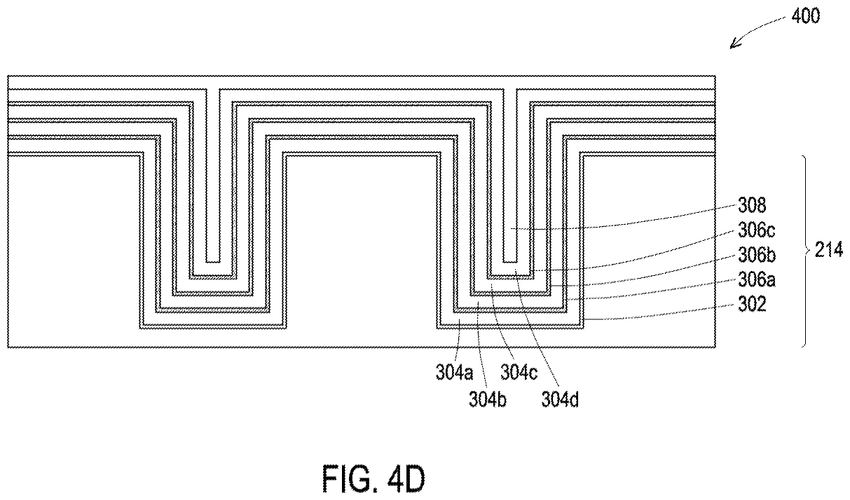

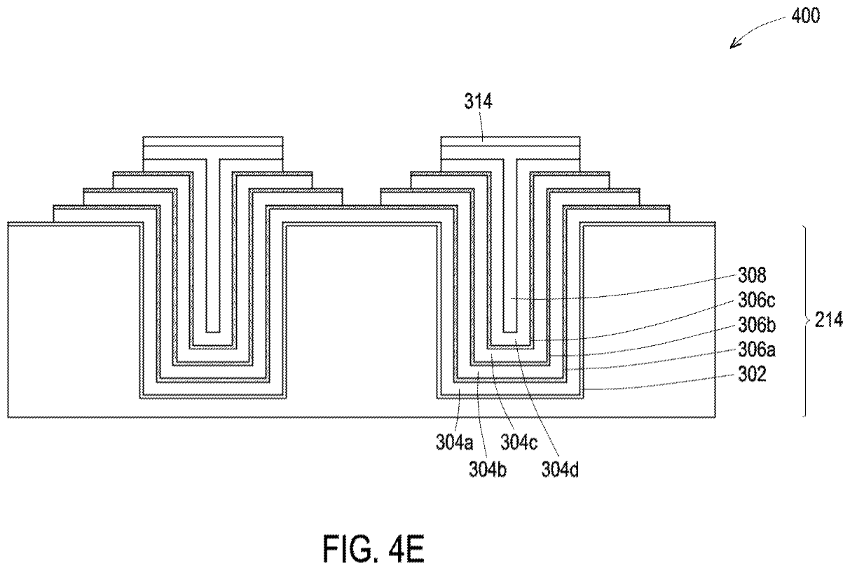

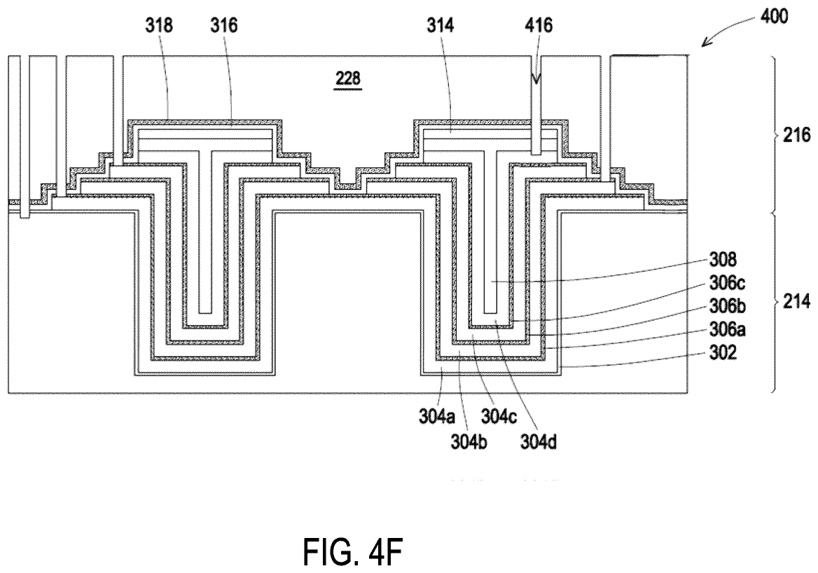

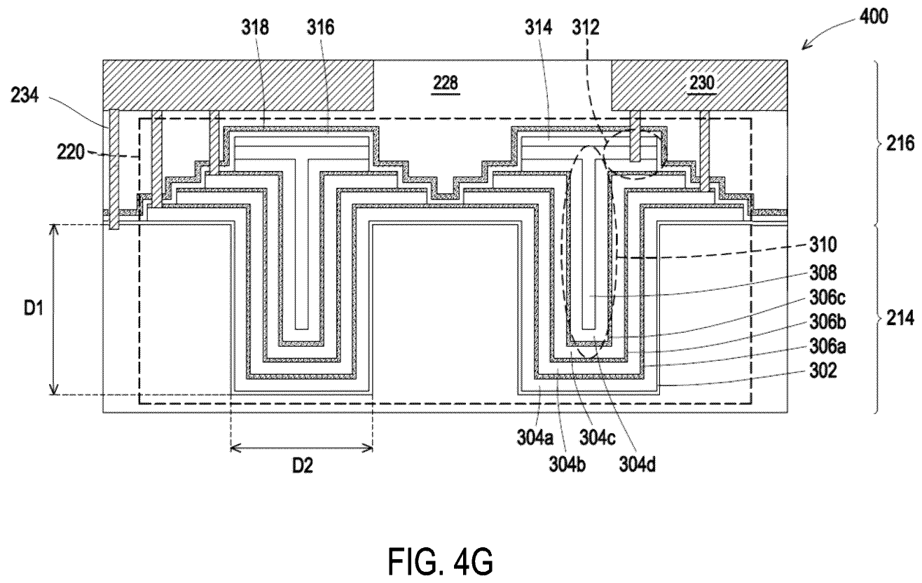

FIGS. 4A-4G are diagrams of an example implementation 400 of forming an in-trench capacitor merged structure described herein. The in-trench capacitor merged structure may correspond to the trench capacitor structure 220.

As shown in FIG. 4A, and as part of forming a semiconductor die (e.g., the semiconductor die 202) several layers of different materials may be formed over the substrate of the device region 214, including a hard mask oxide (HMOX) layer 402, an amorphous perfluoropolymer film (APF) layer 404 and/or a silicon oxynitride (SiON) layer 406. In some implementations, the deposition tool 102 may be used to deposit the HMOX layer 402, the APF layer 404, and/or the SiON layer 406 in a series of PVD operations, ALD operations, CVD operations, epitaxy operations, oxidation operations, other types of deposition operations described in connection with FIG. 1, and/or other suitable deposition operations. In some implementations, the planarization tool 110 may be used to planarize the HMOX layer 402, the APF layer 404, and/or the SiON layer 406 after deposition.

Furthermore, and as part of a patterning operation to form trenches of a trench capacitor structure (e.g., trenches of the trench capacitor structure 220), a bottom anti reflective coating (BARC) layer 408 may be formed on the SiON layer 406. Additionally, or alternatively, a photoresist (PR) layer 410 may be formed on the BARC layer 408. In some implementations, the deposition tool 102 may be used to deposit the BARC layer 408 and/or the PR layer 410 in a spin coating operation, another type of deposition operation described in connection with FIG. 1, and/or another suitable deposition operation.

As shown in FIG. 4B, cavities 412 (e.g., trenches for the trench capacitor structure) are formed through the HMOX layer 402 and into the substrate of the device region 214. In some implementations, a pattern in the PR layer 410 is used to etch the BARC layer 408, the SiON layer 406, the APF layer 404, the HMOX layer 402, and the substrate of the device region 214 to form the cavities 412. The exposure tool 104 may be used to expose the PR layer 410 to a radiation source to pattern the photoresist layer. The developer tool 106 may be used to develop and remove portions of the PR layer 410 to expose the pattern. The etch tool 108 may be used to etch the BARC layer 408, the SiON layer 406, the APF layer 404, the HMOX layer 402, and the substrate of the device region 214 based on the pattern to form the cavities 412 the substrate of the device region. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Further, and in some implementations, the planarization tool 110 may be used to remove remaining portions of the BARC layer 408, the SiON layer 406, and/or the APF layer 404.

Turning to FIG. 4C, the liner layer 302, the conductive layers 304, and the dielectric layers 306 are formed in the trenches (e.g., in the cavities 412). The deposition tool 102 and/or the plating tool 112 may be used to deposit the liner layer 302, the conductive layers 304, and/or the dielectric layers 306 in a series of CVD operations, PVD operations, ALD operations, electroplating operations, other deposition operations described above in connection with FIG. 1, and/or other suitable deposition operations.

In some implementations, a thickness of the conductive layer 304d (e.g., a top-most electrode layer) is such that gaps 414 (e.g., cavities for the merge region 310) remain between co-facing surfaces of the conductive layer 304d.

Alternatively, and in some implementations, a pattern in a photoresist layer is used to etch the conductive layer 304d to form cavities that correspond to the gaps 414. In these implementations, the deposition tool 102 may be used to form a photoresist layer on the conductive layer 304d. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the conductive layer 304d based on the pattern to form the cavities in the conductive layer 304d. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the conductive layer 304d based on a pattern.

As shown in FIG. 4D, and as part of implementation 400, the merged dielectric layer 308 is formed, including portions in the merge region 310 and the lateral region 312. In some implementations, the deposition tool 102 may be used to deposit the merged dielectric layer 308 in an ALD operation. Alternatively, the deposition tool may be used to deposit the merged layer in a high aspect ratio process (HARP), where the high aspect ratio process includes PVD operation or a CVD operation. In some implementations, the planarization tool 110 may be used to planarize the merged dielectric layer 308 after the merged dielectric layer is deposited.

As shown in FIG. 4E, a series of semiconductor processing operations forms the BARC layer 314 on the merged dielectric layer 308 and further forms tiering in the conductive layers 304 that are interspersed with the dielectric layers 306. The tiering may create landing areas and/or offsets to accommodate one or more interconnect structures (e.g., the interconnect structure 234) that connect with the conductive layers 304.

As an example, and as part of the series of semiconductor processing operations, patterns in photoresist layers may be used to etch the conductive layers 304, the dielectric layers 306, the merged dielectric layer 308, and/or the BARC layer 314 to form the tiering. In these implementations, the deposition tool 102 may be used to form the photoresist layers and the exposure tool 104 may be used to expose the photoresist layers to a radiation source to pattern the photoresist layers. The developer tool 106 may be used to develop and remove portions of the photoresist layers to expose the patterns. The etch tool 108 may be used to etch the conductive layers 304, the dielectric layers 306, the merged dielectric layer 308, and/or the BARC layer 314 based on the patterns to form the tiering. In some implementations, the etch operations include a plasma etch operation, a wet chemical etch operation, and/or another type of etch operation. In some implementations, a photoresist removal tool may be used to remove the remaining portions of the photoresist layers (e.g., using a chemical stripper, plasma ashing, and/or another technique). In some implementations, a hard mask layer is used as an alternative technique for etching the etch the conductive layers 304, the dielectric layers 306, the merged dielectric layer 308, and/or the BARC layer 314 based on the patterns.

Turning to FIG. 4F, and as part of forming the trench capacitor structure 220, a series of semiconductor processing operations forms the oxide layer 316 and the SiN layer 318 over the conductive layers 304, the dielectric layers 306, and the merged dielectric layer 308. The deposition tool 102 may be used to deposit the oxide layer 316 and/or the SiN layer 318 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the oxide layer 316 and/or the SiN layer 318 after deposition.

The series of operations further includes forming at least one of the dielectric layer(s) 228 over the trench capacitor structure 220. The deposition tool 102 may be used to deposit the at least one dielectric layer (of the dielectric layer(s) 228) in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the at least one dielectric layer (of the dielectric layer(s) 228) after deposition.

The series of operations of FIG. 4F further includes forming cavities 416 that includes at least one cavity through the at least one dielectric layer, through the SiN layer 318, through the oxide layer 316, and through the merged dielectric layer 308 to expose the conductive layer 304d (e.g., a top-most electrode layer). In some implementations, a pattern in a photoresist layer is used to etch the at least one dielectric layer (of the dielectric layer(s) 228), the SiN layer 318, the oxide layer 316, and the merged dielectric layer 308 to form the at least one cavity. In these implementations, the deposition tool 102 may be used to form the photoresist layer on a top layer of the dielectric layer(s) 228. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the at least one dielectric layer (of the dielectric layer(s) 228), the SiN layer 318, the oxide layer 316, and the merged dielectric layer 308 based on the pattern to form the at least once cavity (of the cavities 416) in the dielectric layer(s) 228. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer(s) 228 based on a pattern.

As shown in FIG. 4G, a series of semiconductor processing operations forms the interconnect structure(s) 234 and one or more layers of the dielectric layer(s) 228. As part of the series of semiconductor processing operations, the deposition tool 102 and/or the plating tool 112 may be used to deposit the interconnect structure(s) 234 and the dielectric layer(s) 228 in a series of CVD operations, PVD operations, ALD operations, electroplating operations, other deposition operations described above in connection with FIG. 1, and/or other suitable deposition operations. In some implementations, the planarization tool 110 may be used to planarize the interconnect structure(s) 234 and/or the dielectric layer(s) 228 after deposition.

The series of semiconductor processing operations of FIG. 4G further includes forming the metallization layer(s) 230. As part of forming the metallization layer(s) 230, the deposition tool 102 and/or the plating tool 112 may be used to deposit the metallization layer(s) 230 on at least one of the dielectric layer(s) 228 in a series of CVD operations, PVD operations, ALD operations, electroplating operations, other deposition operations described above in connection with FIG. 1, and/or other suitable deposition operations. In some implementations, the planarization tool 110 may be used to planarize the metallization layer(s) 230 after deposition.

In some implementations, and as part of the series of semiconductor operations, features are formed from the metallization layer(s) 230. In some implementations, a pattern in a photoresist layer is used to etch the metallization layer(s) 230 and form the features. In these implementations, the deposition tool 102 may be used to form the photoresist layer on the metallization layer(s) 230. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the metallization layer(s) 230 and form the features. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the metallization layer(s) 230 based on a pattern.

As indicated above, FIGS. 4A-4G are provided as an example. Other examples may differ from what is described with regard to FIGS. 4A-4G.

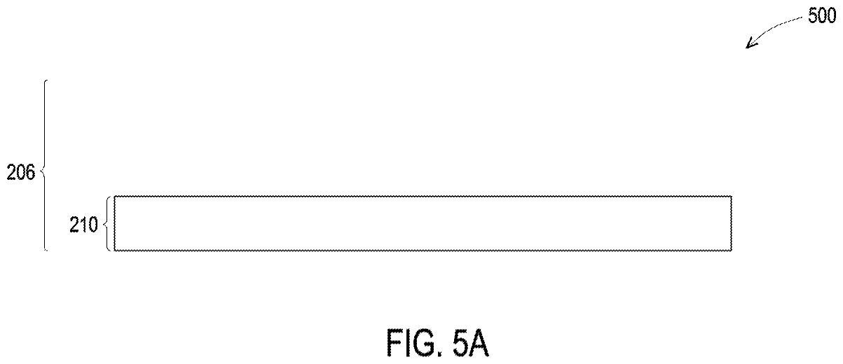

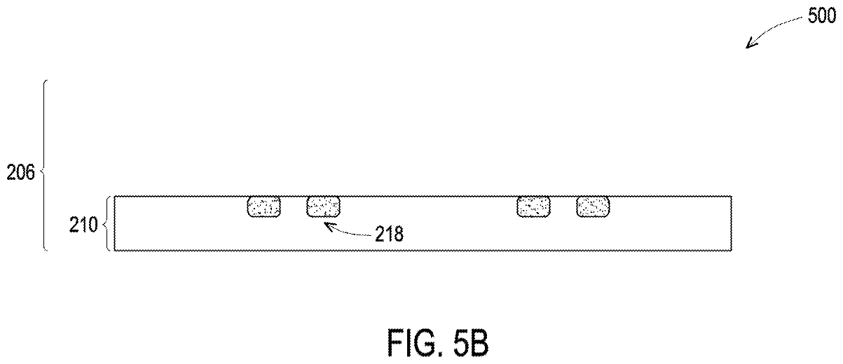

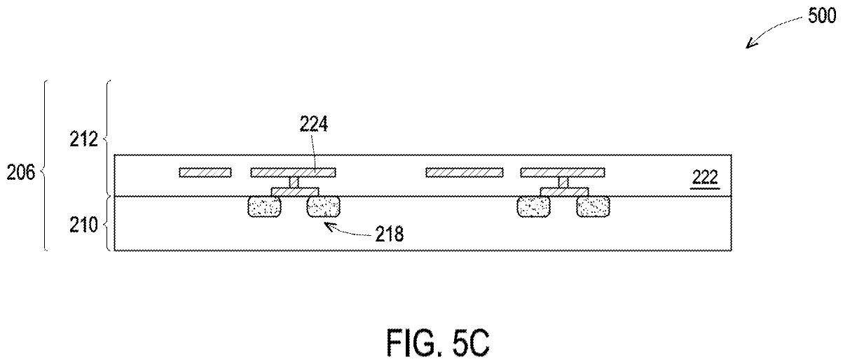

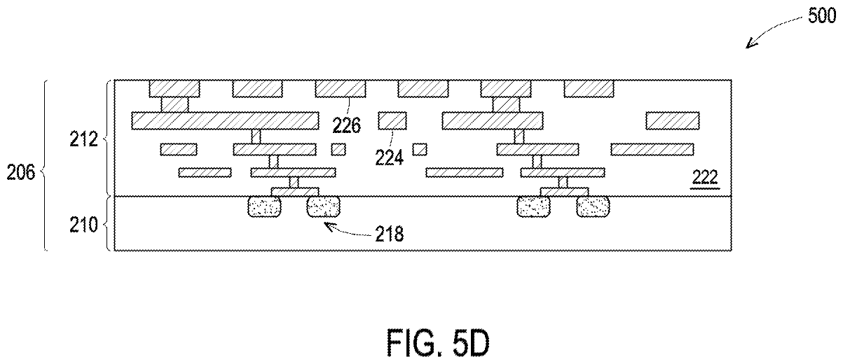

FIGS. 5A-5D are diagrams of an example implementation 500 of forming a semiconductor die described herein. In some implementations, the example implementation 500 includes an example process for forming a portion of the second semiconductor die 206. In some implementations, one or more of the semiconductor processing tools 102-114 and/or the wafer/die transport tool 116 may be used to perform one or more of the operations described in connection with the example implementation 500. In some implementations, one or more operations described in connection with the example implementation 500 may be performed by another semiconductor processing tool.

Turning to FIG. 5A, one or more of the operations in the example implementation 500 may be performed in connection with the semiconductor substrate of the device region 210 of the second semiconductor die 206. The semiconductor substrate of the device region 210 may be provided in the form of a semiconductor wafer or another type of substrate.

As shown in FIG. 5B, one or more semiconductor devices 218 may be formed in the device region 210. For example, one or more of the semiconductor processing tools 102-114 may be used to perform photolithography patterning operations, etching operations, deposition operations, CMP operations, and/or another type of operations to form one or more transistors, one or more capacitors, one or more memory cells, one or more circuits (e.g., one or more ICs), and/or one or more semiconductor devices of another type. In some implementations, one or more regions of the semiconductor substrate of the device region 210 may be doped in an ion implantation operation to form one or more p-wells, one or more n-wells, and/or one or more deep n-wells. In some implementations, the deposition tool 102 may be used to deposit one or more source/drain regions, one or more gate structures, and/or one or more STI regions, among other examples.

As shown in FIG. 5C, a portion of the interconnect region 212 of the second semiconductor die 206 may be formed over and/or on the semiconductor substrate of the device region 210. One or more of the semiconductor processing tools 102-114 may form the interconnect region 212 by forming the dielectric layer(s) 222 and forming a plurality of metallization layer(s) 224 in the dielectric layer(s) 222. For example, the deposition tool 102 may be used to deposit a first layer of the dielectric layer(s) 222 (e.g., using a CVD technique, an ALD technique, a PVD technique, and/or another type of deposition technique), the etch tool 108 may be used to remove portions of the first layer to form recesses in the first layer, and the deposition tool 102 and/or the plating tool 112 may form a first metallization layer of the plurality of metallization layer(s) 224 in the recesses (e.g., using a CVD technique, an ALD technique, a PVD technique, an electroplating technique, and/or another type of deposition technique). At least a portion of the first metallization layer may be electrically connected and/or physically connected with the semiconductor device(s) 218. The deposition tool 102, the etch tool 108, the plating tool 112, and/or another semiconductor processing tool may continue to perform similar processing operations to forming the interconnect region 212 until a sufficient or desired arrangement of metallization layer(s) 224 is achieved.

As shown in FIG. 5D, one or more of the semiconductor processing tools 102-114 may form another layer of the dielectric layer(s) 222, and may form one or more contacts 226 in the layer such that the contact(s) 226 are electrically connected and/or physically connected with one or more of the metallization layer(s) 224. For example, the deposition tool 102 may be used to deposit the layer of the dielectric layer(s) 222 (e.g., using a CVD technique, an ALD technique, a PVD technique, and/or another type of deposition technique), the etch tool 108 may be used to remove portions of the layer to form recesses in the layer, and the deposition tool 102 and/or the plating tool 112 may form the contact(s) 226 in the recesses (e.g., using a CVD technique, an ALD technique, a PVD technique, an electroplating technique, and/or another type of deposition technique).

As indicated above, FIGS. 5A-5D are provided as an example. Other examples may differ from what is described with regard to FIGS. 5A-5D.

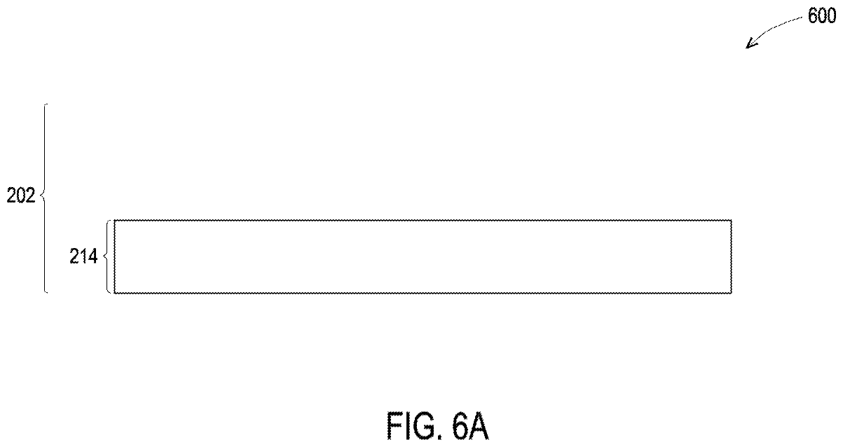

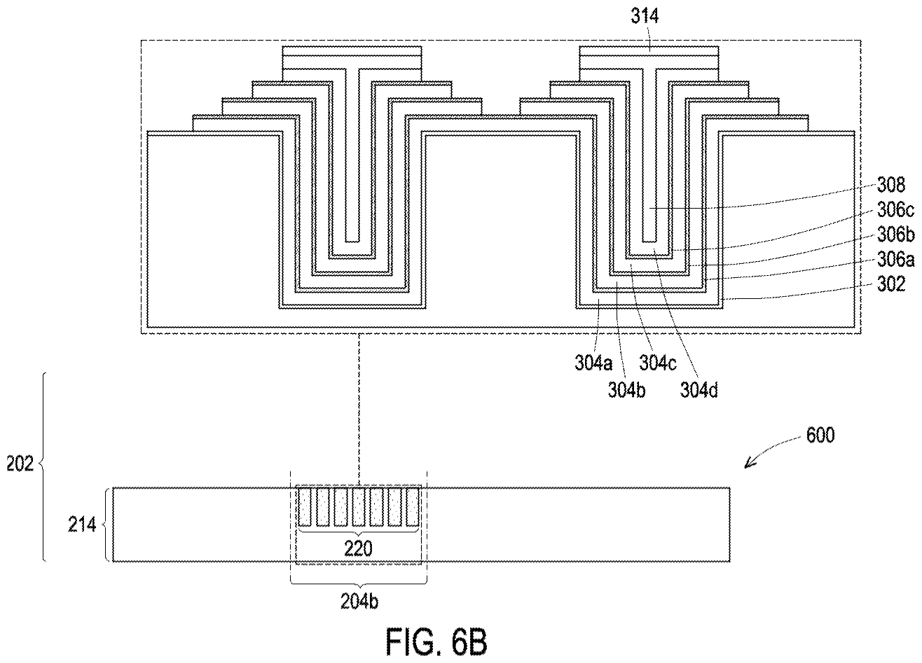

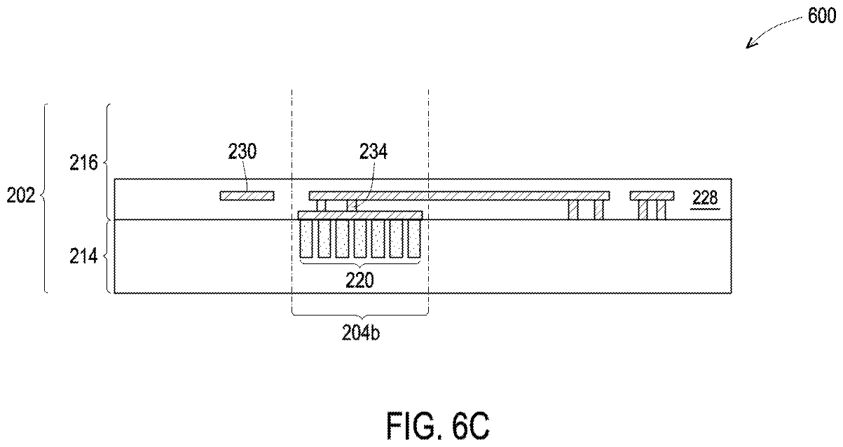

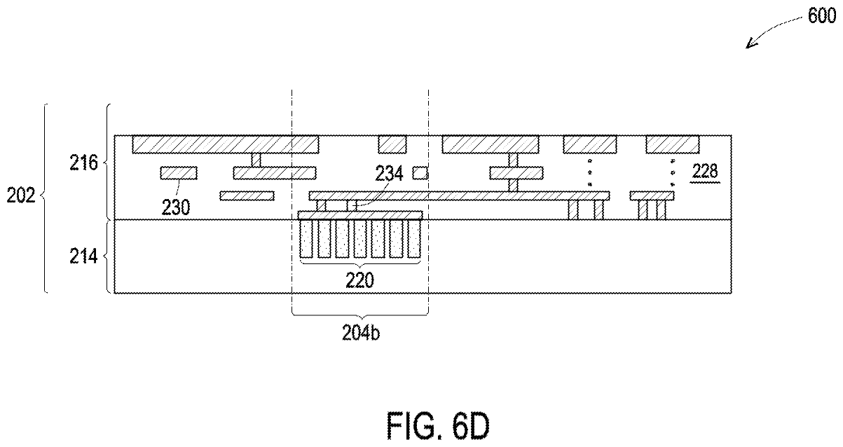

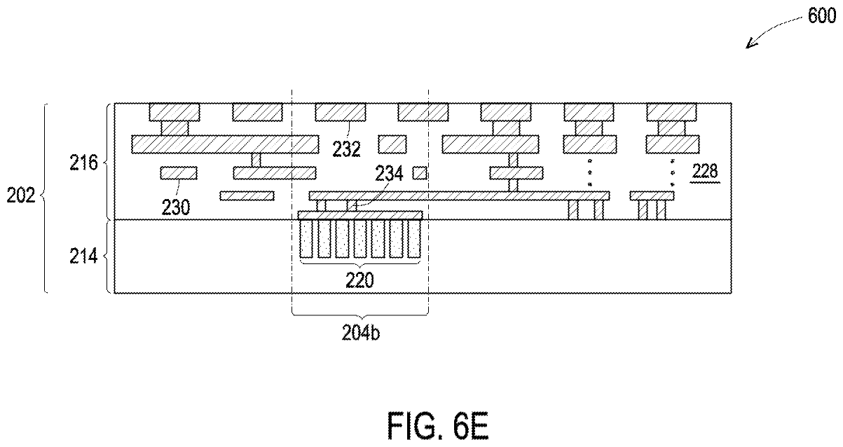

FIGS. 6A-6E are diagrams of an example implementation 600 of forming a semiconductor die described herein. In some implementations, the example implementation 600 includes an example process for forming a portion of the first semiconductor die 202. In some implementations, one or more of the semiconductor processing tools 102-114 and/or the wafer/die transport tool 116 may be used to perform one or more of the operations described in connection with the example implementation 600. In some implementations, one or more operations described in connection with the example implementation 600 may be performed by another semiconductor processing tool.

Turning to FIG. 6A, one or more of the operations in the example implementation 600 may be performed in connection with the semiconductor substrate of the device region 214 of the first semiconductor die 202. The semiconductor substrate of the device region 214 may be provided in the form of a semiconductor wafer or another type of substrate.

As shown in FIG. 6B, the trench capacitor structure 220 may be formed in the device region 214. Using techniques described in connection with FIGS. 4A-4D and elsewhere herein, the one or more semiconductor processing tools 102-114 may form the trench capacitor structure 220. As shown in the detail of FIG. 6B, the trench capacitor structure 220 may include the liner layer 302, the conductive layers 304, the dielectric layers 306, the merged dielectric layer 308, and/or the BARC layer 314.

Formation of the merged dielectric layer 308 may include a thermal cycle that includes a high temperature deposition operation (e.g., an ALD deposition operation at approximately 400° C.) followed by a cooling operation (e.g., exposure of the merged dielectric layer 308 to an ambient environment of approximately 25° C. for a cooling duration). As described in connection with FIG. 3A, one or more mechanical properties of the merged dielectric layer 308, in combination with an architecture of the trench capacitor structure 220, including one or more mechanical properties of a substrate of the device region 214 and/or the conductive layers 304, may reduce a likelihood of cracking and/or delamination within the merge region 310.

In this way, a quality and/or a reliability of an IC device including the trench capacitor structure 220 may be improved to increase a manufacturing yield and reduce an amount of latent field failures during use of the IC device. By improving the manufacturing yield and reducing the amount of latent field failures, an amount of resources to manufacture and support a volume of the IC device (e.g., power, labor, semiconductor manufacturing tools, raw materials, and/or computing resources to manufacture the IC device and/or manage returns of the IC device) may be reduced.

As shown in FIG. 6C, a portion of the interconnect region 216 of the first semiconductor die 202 may be formed over and/or on the semiconductor substrate of the device region 214. One or more of the semiconductor processing tools 102-114 may be used to form the interconnect region 216 by forming one or more dielectric layers 228 and forming one or more metallization layers 230 in the dielectric layer(s) 228. For example, the deposition tool 102 may be used to deposit a first layer of the dielectric layer(s) 228 (e.g., using a CVD technique, an ALD technique, a PVD technique, and/or another type of deposition technique), the etch tool 108 may be used to remove portions of the first layer to form recesses in the first layer, and the deposition tool 102 and/or the plating tool 112 may be used to form a first metallization layer of the metallization layer(s) 230 in the recesses (e.g., using a CVD technique, an ALD technique, a PVD technique, an electroplating technique, and/or another type of deposition technique). The trench capacitor structure 220 in the trench capacitor region 204b may be electrically connected and/or physically connected with one or more of the metallization layer(s) 230 using the interconnect structure 234. As shown in FIG. 6D, the deposition tool 102, the etch tool 108, the plating tool 112, and/or another semiconductor processing tool may continue to perform similar processing operations to continue forming the dielectric layer(s) 228 and/or the metallization layer(s) 230 in the interconnect region 216.

As shown in FIG. 6E, one or more of the semiconductor processing tools 102-114 may be used to form another layer of the dielectric layer(s) 228, and may be used to form one or more contacts 232 in the layer such that the contact(s) 232 are electrically connected and/or physically connected with one or more of the metallization layer(s) 230. For example, the deposition tool 102 may be used to deposit the layer of the dielectric layer(s) 228 (e.g., using a CVD technique, an ALD technique, a PVD technique, and/or another type of deposition technique), the etch tool 108 may be used to remove portions of the layer to form recesses in the layer, and the deposition tool 102 and/or the plating tool 112 may be used to form the contact(s) 232 in the recesses (e.g., using a CVD technique, an ALD technique, a PVD technique, an electroplating technique, and/or another type of deposition technique).

As indicated above, FIGS. 6A-6E are provided as an example. Other examples may differ from what is described with regard to FIGS. 6A-6E.

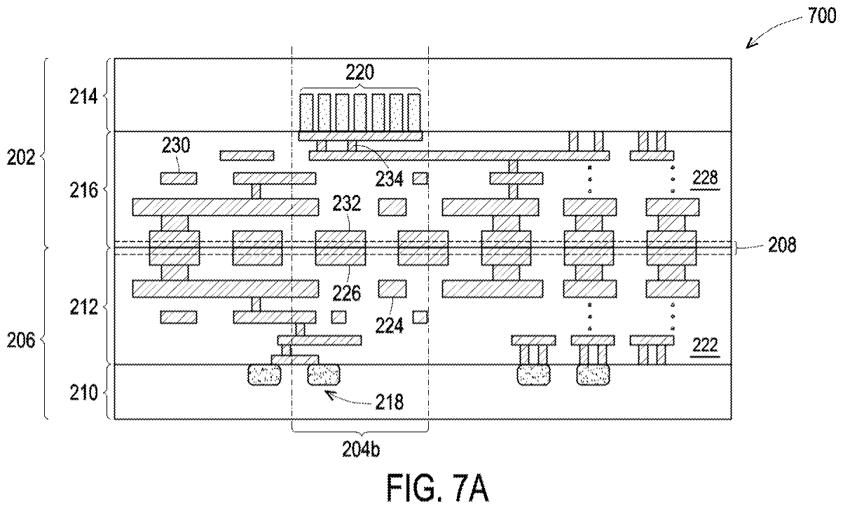

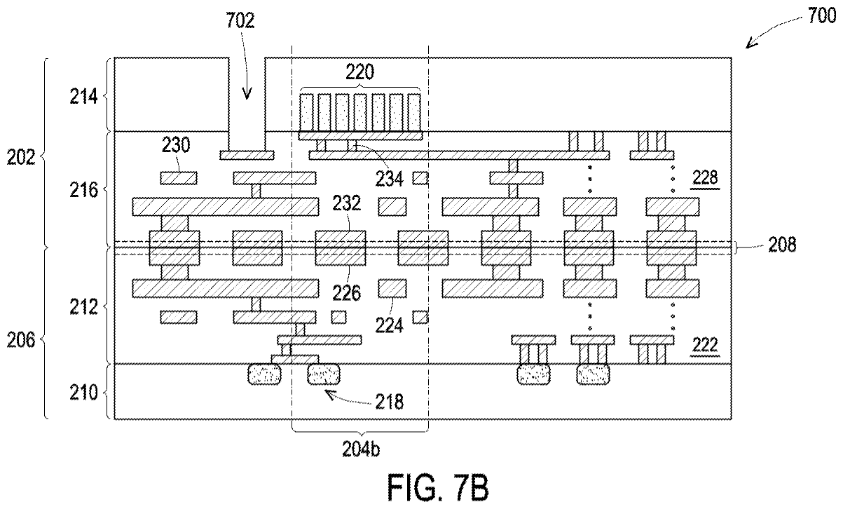

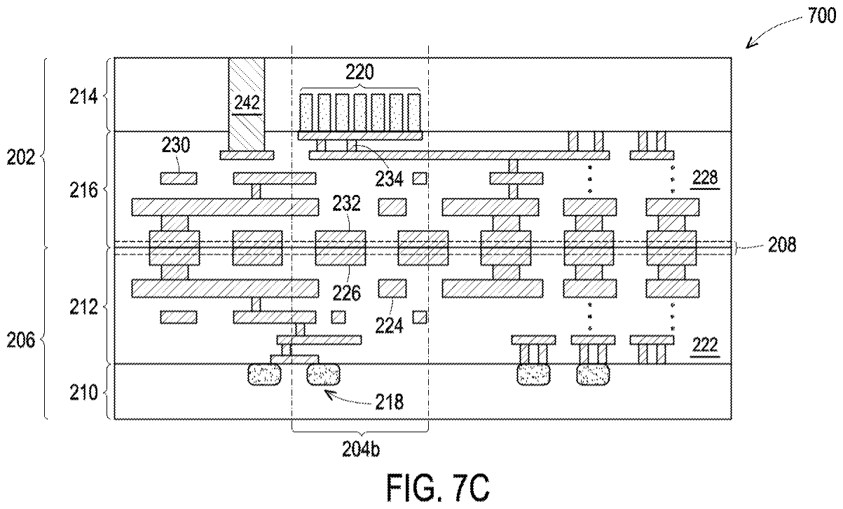

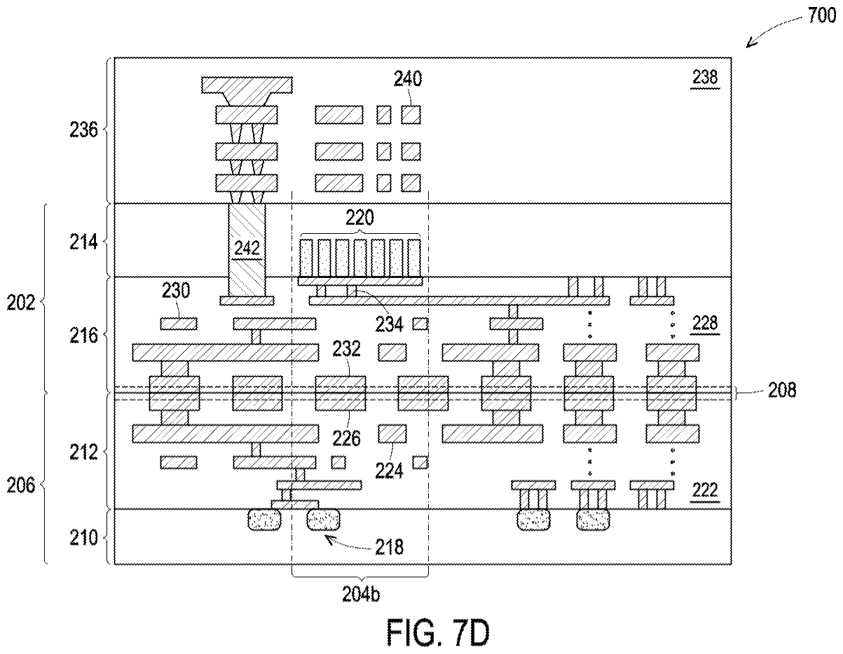

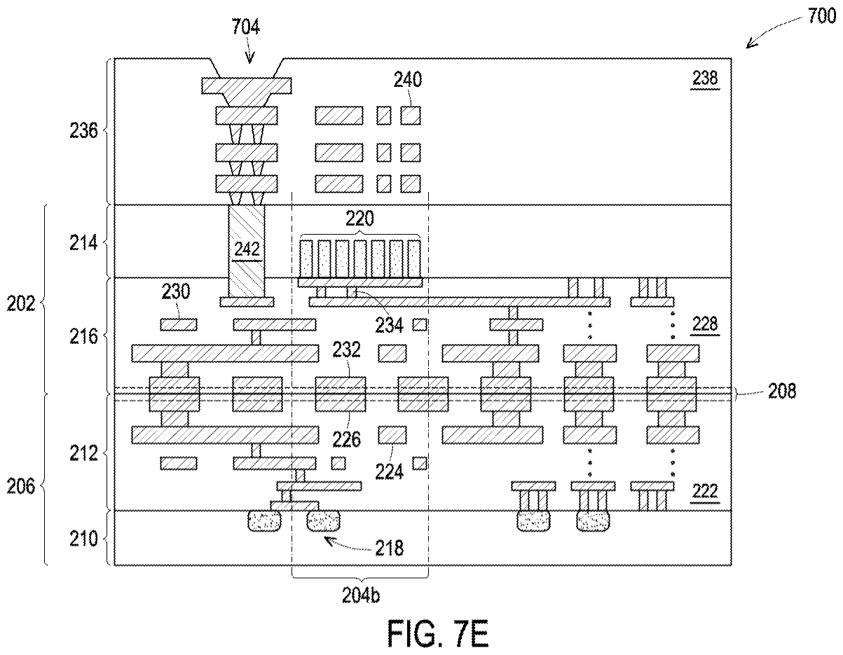

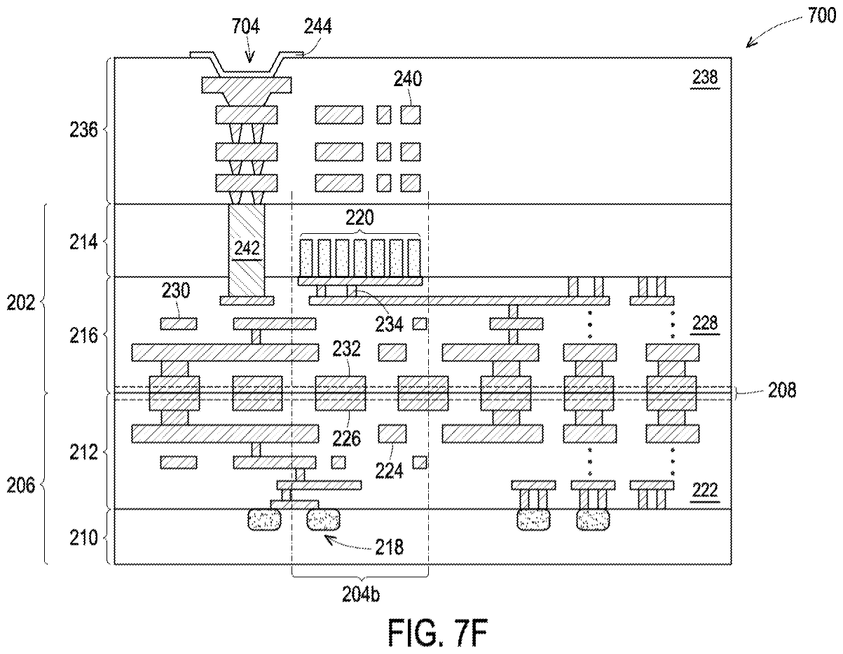

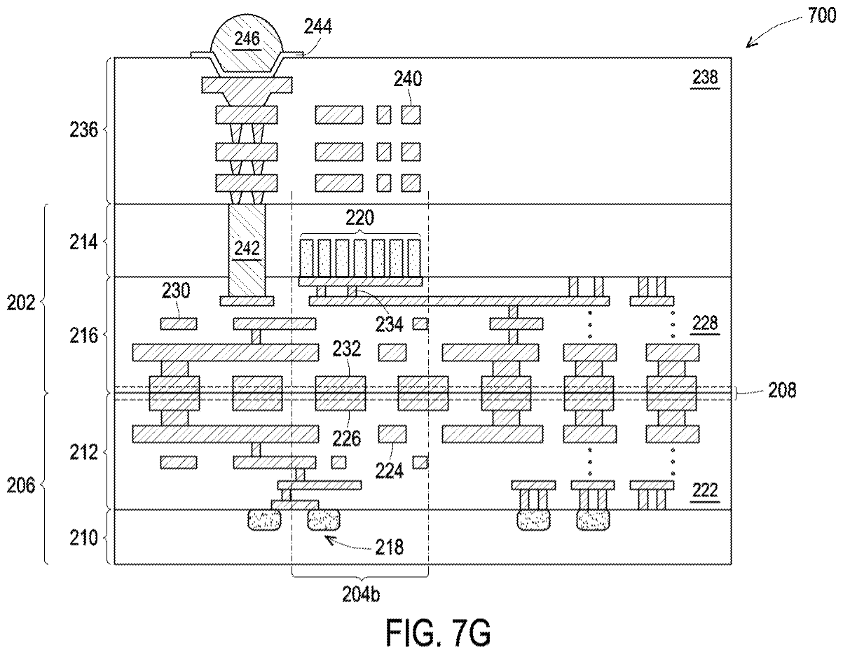

FIGS. 7A-7G are diagrams of an example implementation 700 of forming a portion of a semiconductor die package 200 described herein. In some implementations, one or more operations described in connection with FIGS. 7A-7G may be performed by one or more of the semiconductor processing tools 102-114 and/or the wafer/die transport tool 116. In some implementations, one or more operations described in connection with FIGS. 7A-7G may be performed by another semiconductor processing tool.

As shown in FIG. 7A, the first semiconductor die 202 and the second semiconductor die 206 may be bonded at the bonding interface 208 such that the first semiconductor die 202 and the second semiconductor die 206 are vertically arranged or stacked. The first semiconductor die 202 and the second semiconductor die 206 may be vertically arranged or stacked in a WoW configuration, a die on wafer configuration, a die on die configuration, and/or another direct bonding configuration. The bonding tool 114 may be used to perform a bonding operation to bond the first semiconductor die 202 and the second semiconductor die 206 at the bonding interface 208. The bonding operation may include a direct bonding operation in which bonding of first semiconductor die 202 and the second semiconductor die 206 is achieved through the physical connection of the contact(s) 226 with the contact(s) 232. At the bonding interface 208, a direct metal bonding is formed between the contact(s) 226/232, and a direct dielectric bond is formed between two dielectric layers.

As shown in FIG. 7B, one or more recesses 702 may be formed through the semiconductor substrate of the device region 214 and into a portion of the dielectric layer(s) 228 of the interconnect region 216. The recess(es) 702 may be formed to expose one or more portions of a metallization layer 230 in the interconnection region 216. Thus, the recess(es) 702 may be formed over the one or more portions of a metallization layer 230.

In some implementations, a pattern in a photoresist layer is used to form the recess(es) 702. In these implementations, the deposition tool 102 forms the photoresist layer over the silicon substrate of the device region 214. The exposure tool 104 exposes the photoresist layer to a radiation source to pattern the photoresist layer. The developer tool 106 develops and removes portions of the photoresist layer to expose the pattern. The etch tool 108 etches through the semiconductor substrate of the device region 214 and into a portion of the dielectric layer(s) 228 of the interconnect region 216 to form the recess(es) 702. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recess(es) 702 based on a pattern.

As shown in FIG. 7C, the BTSV structure(s) 242 may be formed in the recess(es) 702. In this way, the BTSV structure(s) 242 extend through the semiconductor substrate the device region 214 and into the interconnect region 216. The BTSV structure(s) 242 may be electrically connected and/or physically connected with the one or more portions of the metallization layer 230 that were exposed through the recess(es) 702.

The deposition tool 102 and/or the plating tool 112 may be used to deposit the BTSV structure(s) 242 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may be used to perform a CMP operation to planarize the BTSV structure(s) 242 after the BTSV structure(s) 242 are deposited.

As shown in FIG. 7D, the redistribution structure 236 of the semiconductor die package 200 may be formed over the first semiconductor die 202. One or more of the semiconductor processing tools 102-114 may be used to form the redistribution structure 236 by forming one or more dielectric layers 238 and forming a plurality of metallization layers 240 in the plurality of dielectric layers 238. For example, the deposition tool 102 may be used to deposit a first layer of the one or more dielectric layers 238 (e.g., using a CVD technique, an ALD technique, a PVD technique, and/or another type of deposition technique), the etch tool 108 may be used to remove portions of the first layer to form recesses in the first layer, and the deposition tool 102 and/or the plating tool 112 may be used to form a first metallization layer of the plurality of metallization layers 240 in the recesses (e.g., using a CVD technique, an ALD technique, a PVD technique, an electroplating technique, and/or another type of deposition technique). At least a portion of the first metallization layer may be electrically connected and/or physically connected with the BTSV structure(s) 242. The deposition tool 102, the etch tool 108, the plating tool 112, and/or another semiconductor processing tool may continue to perform similar processing operations to forming the redistribution structure 236 until a sufficient or desired arrangement of metallization layers 240 is achieved.

As shown in FIG. 7E, recesses 704 may be formed in the one or more dielectric layers 238. The recesses 704 may be formed to expose portions of a metallization layer 240 in the redistribution structure 236. Thus, the recesses 704 may be formed over the one or more portions of a metallization layer 240.

In some implementations, a pattern in a photoresist layer is used to form the recesses 702. In these implementations, the deposition tool 102 forms the photoresist layer on the one or more dielectric layers 238. The exposure tool 104 exposes the photoresist layer to a radiation source to pattern the photoresist layer. The developer tool 106 develops and removes portions of the photoresist layer to expose the pattern. The etch tool 108 etches into the one or more dielectric layers 238 to form the recesses 702. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses 704 based on a pattern.

As shown in FIG. 7F, UBM layers 244 may be formed in the recesses 704. The deposition tool 102 and/or the plating tool 112 may be used to deposit the UBM layers 244 using a CVD technique, a PVD technique, an ALD technique, an electroplating technique, another deposition technique described above in connection with FIG. 1, and/or a deposition technique other than as described above in connection with FIG. 1. In some implementations, a continuous layer of conductive material is deposited on the top surface of the redistribution structure 236, including in the recess 702. The continuous layer of conductive material is then patterned (e.g., by the deposition tool 102, the exposure tool 104, and the developer tool 106) to form a pattern on the continuous layer of the conductive material, and the etch tool 108 removes portions of the continuous layer of the conductive material based on the pattern. Remaining portions of the continuous layer of the conductive material may correspond to the UBM layers 244.

As shown in FIG. 7G, conductive terminals 246 may be formed in the recesses 704 over the UBM layers 244. In some implementations, the plating tool 112 forms the conductive terminals 246 using an electroplating technique. In some implementations, solder is dispensed in the recesses 704 to form the conductive terminals 246.

As indicated above, FIGS. 7A-7G are provided as an example. Other examples may differ from what is described with regard to FIGS. 7A-7G.

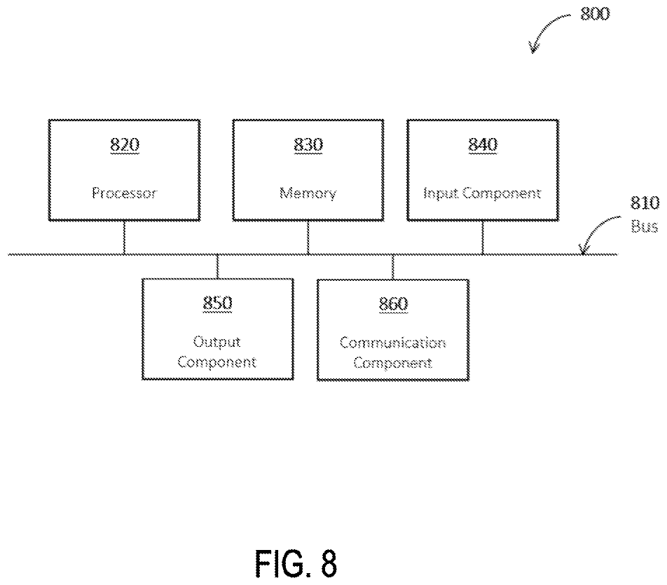

FIG. 8 is a diagram of example components of a device 800 described herein. In some implementations, one or more of the semiconductor processing tools 102-114 and/or the wafer die transport tool 116 may include one or more devices 800 and/or one or more components of the device 800. As shown in FIG. 8, the device 800 may include a bus 810, a processor 820, a memory 830, an input component 840, an output component 850, and/or a communication component 860.

The bus 810 may include one or more components that enable wired and/or wireless communication among the components of the device 800. The bus 810 may couple together two or more components of FIG. 8, such as via operative coupling, communicative coupling, electronic coupling, and/or electric coupling. For example, the bus 810 may include an electrical connection (e.g., a wire, a trace, and/or a lead) and/or a wireless bus. The processor 820 may include a central processing unit, a graphics processing unit, a microprocessor, a controller, a microcontroller, a digital signal processor, a field-programmable gate array, an application-specific integrated circuit, and/or another type of processing component. The processor 820 may be implemented in hardware, firmware, or a combination of hardware and software. In some implementations, the processor 820 may include one or more processors capable of being programmed to perform one or more operations or processes described elsewhere herein.

The memory 830 may include volatile and/or nonvolatile memory. For example, the memory 830 may include random access memory (RAM), read only memory (ROM), a hard disk drive, and/or another type of memory (e.g., a flash memory, a magnetic memory, and/or an optical memory). The memory 830 may include internal memory (e.g., RAM, ROM, or a hard disk drive) and/or removable memory (e.g., removable via a universal serial bus connection). The memory 830 may be a non-transitory computer-readable medium. The memory 830 may store information, one or more instructions, and/or software (e.g., one or more software applications) related to the operation of the device 800. In some implementations, the memory 830 may include one or more memories that are coupled (e.g., communicatively coupled) to one or more processors (e.g., processor 820), such as via the bus 810. Communicative coupling between a processor 820 and a memory 830 may enable the processor 820 to read and/or process information stored in the memory 830 and/or to store information in the memory 830.

The input component 840 may enable the device 800 to receive input, such as user input and/or sensed input. For example, the input component 840 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 850 may enable the device 800 to provide output, such as via a display, a speaker, and/or a light-emitting diode. The communication component 860 may enable the device 800 to communicate with other devices via a wired connection and/or a wireless connection. For example, the communication component 860 may include a receiver, a transmitter, a transceiver, a modem, a network interface card, and/or an antenna.

The device 800 may be used to perform one or more operations or processes described herein. For example, a non-transitory computer-readable medium (e.g., memory 830) may store a set of instructions (e.g., one or more instructions or code) for execution by the processor 820. The processor 820 may execute the set of instructions to perform one or more operations or processes described herein. In some implementations, execution of the set of instructions, by one or more processors 820, causes the one or more processors 820 and/or the device 800 to perform one or more operations or processes described herein. In some implementations, hardwired circuitry may be used instead of or in combination with the instructions to perform one or more operations or processes described herein. Additionally, or alternatively, the processor 820 may be configured to perform one or more operations or processes described herein. Thus, implementations described herein are not limited to any specific combination of hardware circuitry and software.

The number and arrangement of components shown in FIG. 8 are provided as an example. The device 800 may include additional components, fewer components, different components, or differently arranged components than those shown in FIG. 8. Additionally, or alternatively, a set of components (e.g., one or more components) of the device 800 may be used to perform one or more functions described as being performed by another set of components of the device 800.

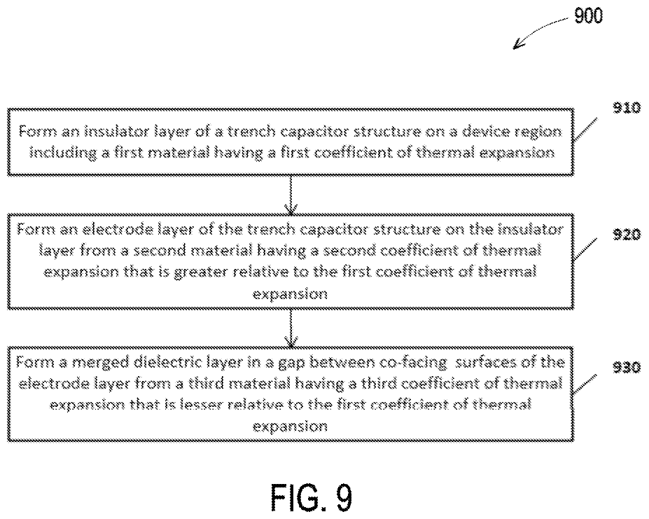

FIG. 9 is a flowchart of an example process 900 associated with an in-trench capacitor merged structure. In some implementations, one or more process blocks of FIG. 9 are performed using one or more semiconductor processing tools (e.g., one or more of the semiconductor processing tools 102-114). Additionally, or alternatively, one or more process blocks of FIG. 9 may be performed using one or more components of device 800, such as processor 820, memory 830, input component 840, output component 850, and/or communication component 860.

As shown in FIG. 9, process 900 may include forming an insulator layer of a trench capacitor structure (block 910). For example, one or more of the semiconductor processing tools 102-114 may be used to form an insulator layer (e.g., the dielectric layer 304c) of a trench capacitor structure (e.g., the trench capacitor structure 220) on a device region (e.g., the substrate in the device region 214) that includes a first material (e.g., an Si material) having a first coefficient of thermal expansion, as described herein.

As further shown in FIG. 9, process 900 may include forming an electrode layer of the trench capacitor structure on the insulator layer from a second material including a second coefficient of thermal expansion that is greater relative to the first coefficient of thermal expansion (block 920). For example, one or more of the semiconductor processing tools 102-114 may be used to form an electrode layer (e.g., the conductive layer 304d) of the trench capacitor structure on the insulator layer from a second material (e.g., a TiN material) including a second coefficient of thermal expansion that is greater relative to the first coefficient of thermal expansion, as described herein.

As further shown in FIG. 9, process 900 may include forming a merged dielectric layer in a gap between co-facing surfaces of the electrode layer from a third material including a third coefficient of thermal expansion that is lesser relative to the first coefficient of thermal expansion (block 930). For example, one or more of the semiconductor processing tools 102-114 may be used to form a merged dielectric layer (e.g., the merged dielectric layer 308) in a gap (e.g., the gap 414) between co-facing surfaces of the electrode layer from a third material (e.g., an SiO₂ material) including third coefficient of thermal expansion that is lesser relative to the first coefficient of thermal expansion, as described herein.

Process 900 may include additional implementations, such as any single implementation or any combination of implementations described below and/or in connection with one or more other processes described elsewhere herein.

In a first implementation, forming the merged dielectric layer in the gap from the second material includes using an atomic layer deposition process.

In a second implementation, alone or in combination with the first implementation, forming the merged dielectric layer in the gap from the second material includes using a high aspect ratio process, wherein the high aspect ratio process includes a chemical vapor deposition process or a physical vapor deposition process.

In a third implementation, alone or in combination with one or more of the first and second implementations, forming the merged dielectric layer in the gap from the second material includes a deposition operation having a thermal cycle that includes a cooling duration, wherein the cooling duration introduces the shrinkage strain within the trench capacitor structure based on a combination of the first coefficient of thermal expansion, the second coefficient of thermal expansion, and the third coefficient of thermal expansion.

In a fourth implementation, alone or in combination with one or more of the first through third implementations, forming the merged dielectric layer in the gap from the second material includes forming a lateral portion of the merged dielectric layer (e.g., a portion of the merged dielectric layer 308 in the lateral region 312) over the insulator layer.

In a fifth implementation, alone or in combination with one or more of the first through fourth implementations, process 900 includes forming a cavity (e.g., the cavity 416) through the lateral portion of the second material and through insulator layer to expose an electrode layer, and forming an interconnect structure (e.g., the interconnect structure 234) in the cavity that connects with the electrode layer.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

Some implementations described herein provide techniques and apparatuses for an IC device including a trench capacitor structure that has a merged region. A material filling the merged region is different than a material that is included in electrode layers of the trench capacitor structure. Furthermore, the material filling the merged region includes a coefficient of thermal expansion and a modulus of elasticity that are lesser relative to a coefficient of thermal expansion and a modulus of elasticity of the material that is included in the electrode layers. During a deposition operation at an elevated temperature, the coefficient of thermal expansion and the modulus of elasticity of the material filling the merged region, in combination with the architecture of the trench capacitor structure, reduce thermally induced stresses and/or strains within the IC device relative to another trench capacitor structure including a merged region and electrode layers of a same material. By reducing the thermal stresses and/or strains within the IC device, a likelihood of cracking defects is reduced.

In this way, a quality and/or a reliability of the IC device may be improved to increase a manufacturing yield and reduce an amount of latent field failures during use of the IC device. By improving the manufacturing yield and reducing the amount of latent field failures, an amount of resources to manufacture and support a volume of the IC device (e.g., power, labor, semiconductor manufacturing tools, raw materials, and/or computing resources to manufacture the IC device and/or manage returns of the IC device) may be reduced.

As described in greater detail above, some implementations described herein provide an IC device. The IC device includes a substrate. The IC device includes a trench capacitor structure within the substrate. The trench capacitor structure includes a plurality of electrode layers of a first material, where the first material has a first modulus of elasticity, and a plurality of insulator layers interspersed with the plurality of electrode layers. The trench capacitor structure includes a merged dielectric layer of a second material in a merge region between co-facing surfaces of a top-most insulator layer of the plurality of insulator layers, where the second material has a second modulus of elasticity that is lesser relative to the first modulus of elasticity.

As described in greater detail above, some implementations described herein provide an IC device. The IC device includes a substrate. The IC device includes a trench capacitor structure within the substrate. The trench capacitor structure includes a plurality of electrode layers of a first material, where the first material has a first coefficient of thermal expansion, and a plurality of insulator layers interspersed with the plurality of electrode layers. The trench capacitor structure includes a merged dielectric layer of a second material in a merge region between co-facing surfaces of a top-most layer of the plurality of electrode layers.

As described in greater detail above, some implementations described herein provide a method. The method includes forming an insulator layer of a trench capacitor structure on a substrate including a first material having a first coefficient of thermal expansion. The method includes forming an electrode layer of the trench capacitor structure on the insulator layer from a second material having a second coefficient of thermal expansion that is greater relative to the first coefficient of thermal expansion. The method includes forming a merged dielectric layer in a gap between co-facing surfaces of the electrode layer from a third material having a third coefficient of thermal expansion that is lesser relative to the first coefficient of thermal expansion.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a substrate; and
a trench capacitor structure within the substrate, comprising:
a plurality of electrode layers comprising a first material,
wherein the first material has a first modulus of elasticity;
a plurality of insulator layers interspersed with the plurality of electrode layers; and
a merged dielectric layer comprising a second material in a merge region between co-facing surfaces of a top-most insulator layer of the plurality of insulator layers,
wherein the second material has a second modulus of elasticity that is lesser relative to the first modulus of elasticity.

2. The integrated circuit device of claim 1, wherein a depth of each trench of the trench capacitor structure is greater relative to a width of each trench of trench capacitor structure.

3. The integrated circuit device of claim 1, wherein the first material comprises a titanium nitride material, and wherein the second material comprises:
an oxide material.

4. The integrated circuit device of claim 3, wherein the oxide material comprises:
an aluminum oxide material,
a zirconium oxide material, or
a silicon dioxide material.

5. The integrated circuit device of claim 1, wherein the substrate comprises:
a third material having a third modulus of elasticity,
wherein the third modulus of elasticity is lesser relative to the first modulus of elasticity, and
wherein the third modulus of elasticity is greater relative to the second modulus of elasticity.

6. The integrated circuit device of claim 5, wherein a ratio of the third modulus of elasticity to the second modulus of elasticity is greater than approximately 5:2.

7. An integrated circuit device, comprising:
a substrate;
a trench capacitor structure within the substrate, comprising:
a plurality of electrode layers comprising a first material,
wherein the first material has a first coefficient of thermal expansion;
a plurality of insulator layers interspersed with the plurality of electrode layers; and
a merged dielectric layer comprising a second material in a merge region between co-facing surfaces of a top-most layer of the plurality of electrode layers,
wherein the second material has a second coefficient of thermal expansion that is lesser relative to the first coefficient of thermal expansion.

8. The integrated circuit device of claim 7, wherein the first material comprises:
a titanium nitride material.

9. The integrated circuit device of claim 7, wherein the second material comprises:
a polyimide material.

10. The integrated circuit device of claim 7, wherein the merged dielectric layer excludes co-facing surfaces in contact with each other and that form an interface.

11. The integrated circuit device of claim 7, wherein the merged dielectric layer is on a top-most insulator layer of the plurality of insulator layers.

12. The integrated circuit device of claim 7, wherein the merged dielectric layer includes a portion outside the merge region and further comprising:
an interconnect structure passing through the portion and to a top-most electrode layer of the plurality of electrode layers.

13. The integrated circuit device of claim 12, wherein the substrate comprises:
a third material having a third coefficient of thermal expansion,
wherein the third coefficient of thermal expansion is lesser relative to the first coefficient of thermal expansion, and
wherein the third coefficient of thermal expansion is greater relative to the second coefficient of thermal expansion.

14. The integrated circuit device of claim 13, wherein a ratio of the third coefficient of thermal expansion to the second coefficient of thermal expansion is greater than approximately 7:1.

15. A method, comprising:
forming an insulator layer of a trench capacitor structure on a device region including a first material having a first coefficient of thermal expansion;
forming an electrode layer of the trench capacitor structure on the insulator layer from a second material having a second coefficient of thermal expansion that is greater relative to the first coefficient of thermal expansion; and
forming a merged dielectric layer in a gap between co-facing surfaces of the electrode layer from a third material having a third coefficient of thermal expansion that is lesser relative to the first coefficient of thermal expansion.

16. The method of claim 15, wherein forming the merged dielectric layer in the gap from the second material includes:
using an atomic layer deposition process.

17. The method of claim 15, wherein forming the merged dielectric layer in the gap from the second material includes:
using a high aspect ratio process,
wherein the high aspect ratio process includes a chemical vapor deposition process or a physical vapor deposition process.

18. The method of claim 15, wherein forming the merged dielectric layer in the gap from the second material includes:
a deposition operation having a thermal cycle that includes a cooling duration,
wherein the cooling duration introduces the shrinkage strain within the trench capacitor structure based on a combination of the first coefficient of thermal expansion, the second coefficient of thermal expansion, and the third coefficient of thermal expansion.

19. The method of claim 15, wherein forming the merged dielectric layer in the gap from the second material includes forming a lateral portion of the merged dielectric layer over the insulator layer.

20. The method of claim 19, further comprising:
forming a cavity through the lateral portion of the second material and through insulator layer to expose an electrode layer; and
forming an interconnect structure in the cavity that connects with the electrode layer.
